(19) United States
(12) Patent Application Publication
(10) Pub. No.: US 2009/0130581 A1
(43) Pub. Date: May 21, 2009

(54) DEVELOPER COMPOSITION AND METHOD FOR PREPARING THE SAME, AND METHOD FOR FORMING RESIST PATTERN

(76) Inventors: Kaoru Ishikawa, Kawasaki-shi (JP); Koichi Misumi, Kawasaki-shi (JP); Koji Saito, Kawasaki-shi (JP)

Correspondence Address: KNOBBE MARTENS OLSON & BEAR LLP, 2040 MAIN STREET, FOURTEENTH FLOOR, IRVINE, CA, 92614, US

(21) Appl. No.: 11/817,127

(22) PCT Filed: Apr. 7, 2006
(86) PCT No.: PCT/JP2006/307431

§ 371 Date: Aug. 24, 2007

(30) Foreign Application Priority Data
Apr. 22, 2005 (JP) 2005-124864

(51) Int. Cl. G03G 9/00; G03F 7/20

(52) U.S. Cl. 430/108.2; 430/108.3; 430/325; 430/137.1

(57) ABSTRACT

There is provided a developer composition which can from a good thick-film resist pattern and is less likely to cause frothing. This composition is a developer composition used to form a thick-film resist pattern on a substrate, and contains an organic quaternary ammonium base as a main component, an anionic surfactant represented by the following general formula (I), and a defoaming agent selected from the group consisting of a silicone-based defoaming agent, an alcohol-based defoaming agent and a nonionic surfactant-based defoaming agent:

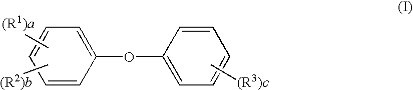

R¹ in the formula (I) represents an alkyl or alkoxy group having 5 to 18 carbon atoms; “a” represents 1 or 2; R² and R³ independently represent an ammonium sulfonate group, a substituted ammonium sulfonate group, or a group represented by the following general formula (II); “b” represents an integer of 0 or 1 to 3; and “c” represents an integer of 1 to 3; and

—SO₃M (II)

wherein M in the formula (II) represents a metal atom.

### TECHNICAL FIELD

The present invention relates to a developer composition used to form a thick-film resist pattern and a method for preparing the same, and a method for forming a resist pattern using the developer composition.

This application claims priority on Japanese Patent Application No. 2005-124864 filed on Apr. 22, 2005, the disclosure of which is incorporated herein by reference.

### BACKGROUND ART

A thick-film resist pattern is used to form a bump or a metal post through a plating step. The bump or metal post can be formed, for example, by forming a thick-film photoresist layer having a thickness of 20 μm on a substrate, exposing thick-film photoresist layer through a predetermined mask pattern, developing the layer to form a thick-film resist pattern in which the portion constituting the bump or metal post is selectively removed (peeled), embedding a conductor such as copper in the removed portion (non-resist portion) through plating, and removing the resist pattern in the vicinity of the embedded conductor.

While an aqueous alkali solution is commonly used to develop a resist pattern, there arises a problem that scum residue is likely to be formed after the development in a thick-film resist pattern. The reason is considered that a resin component such as an acryl resin or a vinyl resin is commonly added in the thick-film resist for the purpose of properly controlling physical and chemical characteristics and thus such a resin component cannot be sufficiently removed in a developer used to form a resist pattern. In the case of the thick-film resist, higher selective dissolving capability (dimensional controllability) is required to the developer as compared with the case of using in a thin-film resist having a thickness around 1 μm.

To the contrary, the following patent document 1 proposes, as a developer composition for resist capable of decreasing scum residue as small as possible after the developing treatment, a developer composition prepared by adding an anionic surfactant having an ammonium sulfonate group or a sulfonic acid-substituted ammonium group to an aqueous solution containing an organic quaternary ammonium salt such as trimethylammonium hydroxide as a main component.

The following patent document 2 proposes a developer composition, which contains the same anionic surfactant as that in the patent document 1 and is excellent in dimensional controllability of a resist pattern.

The following patent document 3 describes a developer composition which contains an anionic surfactant having a substituent constituting a sulfonic acid metal salt and exhibits a high dissolution rate (high developing sensitivity).

Patent document 1: Japanese Patent No. 2,589,408

Patent document 2: Japanese Unexamined Patent Application, First Publication No. 2005-4093

Patent document 3: Japanese Unexamined Patent Application, First Publication No. 2005-17857

### DISCLOSURE OF THE INVENTION

### Problem to be Solved by the Invention

However, these developer compositions containing the surfactant added therein are excellent in characteristics of forming a good resist pattern, but have a problem that they are likely to cause frothing. When severe frothing problem occurs or foam thus formed does not disappear for a long time, a waste fluid tank is filled with foam and the capacity of the waste fluid tank is occupied with the foam in vain. Therefore, it is necessary to remove the foam by periodically adding a defoaming agent in the waste fluid tank, and frothing itself constitutes a problem.

Under these circumstances, the present invention has been made and an object thereof is to provide a developer composition which can form a good thick-film resist pattern and is less likely to cause frothing, and a method for producing the same, and a resist pattern forming method using the developer composition.

The developer composition of the present invention is a developer composition which is used to form a thick-film resist pattern on a substrate, comprising an organic quaternary ammonium base as a main component, an anionic surfactant represented by the following general formula (I), and a defoaming agent selected from the group consisting of a silicone-based defoaming agent, an alcohol-based defoaming agent and a nonionic surfactant-based defoaming agent:

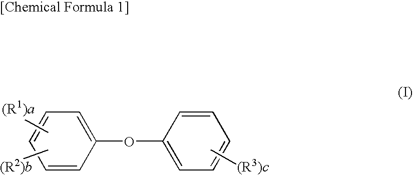

R¹ in the formula (I) represents an alkyl or alkoxy group having to 18 carbon atoms and “a” represents 1 or 2; R² represents an ammonium sulfonate group, a substituted ammonium sulfonate group, or a group represented by the following general formula (II) and “b” represents an integer of 0 or 1 to 3; and R³ represents an ammonium sulfonate group, a substituted ammonium sulfonate group, or a group represented by the following general formula (II) and “c” represents an integer of 1 to 3, provided that when a plurality of R¹(s) are present, they may be the same or different from each other, when a plurality of R² (s) are present, they may be the same or different from each other, and when a plurality of R³ (s) are present, they may be the same or different from each other; and

[Chemical Formula 2]

—SO₃M (II)

wherein M in the formula (II) represents a metal atom.

The method for forming a resist pattern of the present invention comprises the steps of forming a thick-film resist layer having a thickness of 5 to 150 μm on a substrate, selectively exposing the thick-film resist layer, and developing the thick-film resist layer with the developer composition according to any one of claims 1 to 3 after the exposure to form a thick-film resist pattern.

The method for preparing a developer composition is a method for preparing a developer composition used to form a thick-film resist pattern on a substrate, which comprises adding a defoaming agent selected from the group consisting of a silicone-based defoaming agent, an alcohol-based defoaming agent and a nonionic surfactant-based defoaming agent to a developer body containing an organic quaternary ammonium base as a main component and an anionic surfactant represented by the above general formula (I).

### EFFECT OF THE INVENTION

The present invention provides a developer composition which can form a good thick-film resist pattern and is less likely to cause frothing, and a method for producing the same, and a resist pattern forming method using the developer composition.

### BEST MODE FOR CARRYING OUT THE INVENTION

### Developer Composition

The developer composition of the present invention is prepared by adding a defoaming agent to a developer body.

### (Developer Body)

The developer body in the present invention is not specifically limited as long as it is a developer which contains an organic quaternary ammonium base as a main component, and also contains an anionic surfactant represented by the general formula (I).

Organic Quaternary Ammonium Base

The organic quaternary ammonium base is not specifically limited as long as it is used in a developer composition for resist and includes, for example, a quaternary ammonium base having a lower alkyl group or a lower hydroxyalkyl group. The lower alkyl group or lower hydroxyalkyl group has 1 to 5 carbon atoms, preferably from 1 to 3 carbon atoms, and more preferably 1 or 2 carbon atoms.

Specific examples of the organic quaternary ammonium base include tetramethylammonium hydroxide or trimethyl (2-hydroxyethyl)ammonium hydroxide, that is, choline, tetrapropylammonium hydroxide or the like. These organic quaternary ammonium bases may be used alone or in combination.

The organic quaternary ammonium base is not specifically limited and is commonly used in the amount within a range from about 0.1 to 10% by mass, and preferably from 2 to 5% by mass, in the developer body. A solvent of the developer body is commonly water.

Anionic Surfactant

In the general formula (I), R¹ is an alkyl group or an alkoxy group, and has 5 to 18 carbon atoms.

The number “a” of the substituent represented by R¹ is from 1 or 2, and preferably 1.

When a plurality of R¹(s) are present, they may be the same or different from each other.

R² is an ammonium sulfonate group (—SO₃NH₄), a substituted ammonium sulfonate group, or a group represented by the general formula (II).

The substituted ammonium sulfonate group is a group in which one or more hydrogen atoms of an ammonium sulfonate group are substituted and the number of substituents may be 1 (mono-substituted), 2 (di-substituted), 3 (tri-substituted) or 4 (tetra-substituted). Examples of the substituent include an alkyl group having 1 to 3 carbon atoms and a hydroxyalkyl group having 1 to 3 carbon atoms, and specific examples thereof include CH₃, —C₂H₅, —CH₂OH, and —C₂H₄OH.

In the general formula (II), M represents a metal atom. M is not specifically limited as long as it is a metal atom which can form a sulfonic acid metal salt, but is preferably sodium, potassium, or calcium. In view of cost, sodium is more preferable.

When M is sodium, the general formula (II) is represented by —SO₃Na. When M is potassium, the general formula (II) is represented by —SO₃K. When M is calcium, the general formula (II) is represented by —SO₃Ca_{1/2}.

The number “b” of the substituent represented by R² is an integer of 0 or 1 to 3, preferably 0 or 1, and more preferably 1.

When a plurality of R²(s) are present, they may be the same or different from each other. For example, two or more groups represented by the general formula (II) are present as R², M(s) may be the same or different from each other.

R³ is as defined in R². R² and R³ may be same or different from each other.

The number “c” of the substituent represented by R³ is an integer of 1 to 3, and preferably 1 or 2.

When a plurality of R³(s) are present, they may be the same or different from each other. For example, two or more groups represented by the general formula (II) are present as R³, M(s) may be the same or different from each other.

Specific examples of the anionic surfactant represented by the general formula (I) include ammonium alkyldiphenylether sulfonate, tetramethylammonium alkyldiphenylether sulfonate, trimethylethanolammonium alkyldiphenylether sulfonate, triethylammonium alkyldiphenylether sulfonate, ammonium alkyldiphenylether disulfonate, diethanolammonium alkyldiphenylether disulfonate, tetramethylammonium alkyldiphenylether disulfonate, sodium alkyldiphenylether sulfonate, sodium alkyldiphenylether disulfonate, potassium alkyldiphenylether sulfonate, potassium alkyldiphenylether disulfonate, calcium alkyldiphenylether sulfonate, calcium alkyldiphenylether disulfonate; and a compound represented by the following general formula (III).

Among these, a compound represented by the following general formula (III) is preferable.

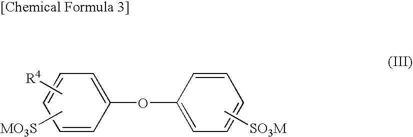

R⁴ in the formula is as defined in R¹. Also, M is as defined above. For example, it is possible to use those in which R⁴ is —C₁₂H₂₅ and M is Na.

The anionic surfactants represented by the general formula (I) may be used alone or in combination.

The other anionic surfactant used commonly in a developer for resist can also be used in combination, but the anionic surfactant represented by the general formula (I) is preferably a main component of the anionic surfactant contained in the developer body. As used herein, the main component means that “it is not contained as a trace amount of impurities in the anionic surfactant” and preferably means that “the amount thereof is the largest in the anionic surfactant contained in the developer body”. The content of the anionic surfactant represented by the general formula (I) in the developer body is preferably 50% by mass or more, more preferably 80% by mass or more, and may be 100% by mass.

The amount of the anionic surfactant contained in the developer body (the total amount when plural kinds of anionic surfactants are used in combination) is preferably within a range from 500 to 100,000 ppm, and more preferably from 1,000 to 50,000 ppm, based on the developer body. By controlling the content of the anionic surfactant to the lower limit or more within the above range, it is possible to enhance the effect of wettability and to enhance resolution. By controlling the content to the upper limit or less within the above range, good dissolution selectivity between the irradiated area and the unirradiated area upon exposure can be obtained and also thickness loss of the unirradiated area can be suppressed, and thus a good resist shape can be obtained.

Other Components

To the developer body, in addition to the organic quaternary ammonium base and the anionic surfactant, additive components, which have used conventionally in a developer for resist, such as humectants, stabilizers, dissolution aids and cationic surfactants for improving dissolution selectivity between the exposed area and the unexposed area of the resist film can be added, if necessary. These additive components may be used alone or in combination.

### (Defoaming Agent)

As the defoaming agent in the present invention, for example, it is possible to use a defoaming agent composed of an oily matter having small volatility and a large diffusing power, such as a silicone-based defoaming agent; a defoaming agent composed of a water-soluble surfactant, such as a nonionic surfactant-based defoaming agent, or an alcohol-based defoaming agent.

As the silicone-based defoaming agent, commercially available silicone-based defoaming agents can be used. Examples thereof include KS-66 (manufactured by Shin-Etsu Chemical Co., Ltd.), TSA737 (manufactured by GE Toshiba Silicones), FS Antiform 544 (manufactured by Dow Corning Co.), and FS Antiform 90 (manufactured by Dow Corning Co.).

Specific examples of the alcohol-based defoaming agent include methanol, ethanol, and butanol.

Specific examples of the nonionic surfactant-based defoaming agent include sorbitan acid fatty acid ester and acetylene glycol. Examples of commercially available products include PRONAL C-448 (manufactured by Toho Chemical Industry Co., Ltd.), PRONAL EX-300 (manufactured by Toho Chemical Industry Co., Ltd.), NEOCREL TO-1 and NEOCREL TO-2 (all of which are manufactured by TAKEMOTO OIL & FAT Co.); and ACETYLENOL EL, ACETYLENOL EH, ACETYLENOL E40 and ACETYLENOL E100 (all of which are manufactured by Kawaken Fine Chemicals Co., Ltd.).

These defoaming agents may be used alone or in combination.

The amount of the defoaming agent varies depending on the kind of the defoaming agent, but is commonly controlled within a range from about 1 to 100,000 ppm, based on the developer body. When the amount of the defoaming agent is 1 ppm or more and 100,000 ppm or less, sufficient defoaming effect can be obtained, and thus it is preferred to decide the amount of the defoaming agent within the above range.

### Defoaming Reproducibility Test

In the case of selecting the defoaming agent, it is preferred to apply the following defoaming reproducibility test.

First, 10 g of a developer body to be used is charged in a screw vial having a diameter of 40 mm and a capacity of 110 ml and then stirred for 15 seconds to cause frothing (frothing step). After standing until the height of the foam becomes 25 mm, it is confirmed for 5 minutes that the height of the foam is 25 mm. The defoaming agent may be selected by simultaneously performing the frothing step with respect to plural defoaming agents.

Next, the defoaming agent to be subjected to the test is charged in the screw vial immediately after the frothing step until the height of the foam in the screw vial becomes 1 mm or less (defoaming step). At this time, the height of the foam is taken as H1. The defoaming agent may be appropriately diluted with pure water. In the defoaming step, the defoaming agent is preferably added little by little while confirming the defoaming state. For example, the defoaming agent is preferably added in an addition rate within a range from 1 to 0.001 g/second, and more specifically 0.1 g/second.

After the defoaming step, the liquid in the screw vial is stirred for 10 seconds (refrothing step). At this time, the height of foam (H2) is measured.

In such a defoaming reproducibility test, the smaller the amount of the defoaming agent required to be added until the foam disappears in the defoaming step, the higher the effect of removing the foam thus formed. The amount of the defoaming agent required to be added until the foam disappears in the defoaming step is preferably 2 g or less.

When the defoaming agent is used after being diluted, the amount (mass) of the defoaming agent does not mean the amount of a dilute solution, but the amount (mass) of only the defoaming agent in the dilute solution.

The lower the height of foam (H2) in the refrothing step, the higher the effect of suppressing frothing, and frothing is less likely to be caused even when stirred. The smaller the height of the foam (H2) in the refrothing step, the better. The height of the foam is preferably 25 mm or less, and more preferably 10 mm or less.

When the results of the defoaming reproducibility test satisfy the above preferable range, it is possible to obtain a developer composition which is less likely to cause frothing so that an operation of periodically adding a defoaming agent in a waste fluid tank in an actual on-site is not required.

### [Method for Preparing Developer Composition]

The developer composition of the present invention can be obtained by using an organic quaternary ammonium base as a main component, and adding a defoaming agent to a developer body containing the above specific anionic surfactant, followed by uniform mixing.

In the case of selecting the defoaming agent, it is preferred to use a defoaming agent in which the defoaming reproducibility test is carried out using the developer body to be used and the amount required until foam disappear in the defoaming step is 2 g or less and the height of the foam measured in the refrothing step is 25 mm or less.

[Method for forming Resist Pattern]

The developer composition of the present invention is used to form a thick-film resist pattern on a substrate.

Namely, the method for forming a resist pattern of the present invention comprises the steps of forming a thick-film resist layer having a thickness of 5 to 150 μm on a substrate, selectively exposing the thick-film resist layer, and developing the developer composition of the present invention after the exposure to form a thick-film resist pattern.

The step of forming a thick-film resist layer and the exposure step can be used using appropriately a known technique. Also, the developing step can be carried out in the same manner as in a known technique, except for using the developer composition of the present invention as a developer.

The method for forming a thick-film resist pattern of the present invention can be carried out, for example, in the following manner. Namely, a solution of a resist composition is applied on a substrate and a solvent is removed by heating (prebaking) to form a coating film having a desired thickness. As the method for coating the solution on the substrate to be treated, for example, a spin coating method, a roll coating method, a screen printing method and an applicator method can be employed.

The conditions of prebaking the coating film vary depending on the kind and content of the respective components in the composition, and the thickness of the coating film, but the prebaking is commonly carried out at a temperature within a range from 70 to 130° C., and preferably from 80 to 120° C., for about 2 to 60 minutes.

The thickness of the photoresist layer is within a range from 5 to 150 μm, preferably from 10 to 150 μm, more preferably from 20 to 120 μm, and still more preferably from 20 to 75 μm.

The resulting photoresist layer is selectively irradiated with (exposed to) radiation, for example, ultraviolet ray having a wavelength of 300 to 500 nm or visible ray. As a radiation source of radiation, for example, a low-pressure mercury lamp, a high-pressure mercury lamp, an ultrahigh-pressure mercury lamp, a metal halide lamp and an argon gas laser can be used. As used herein, radiation means ultraviolet ray, visible ray, far ultraviolet ray, X-ray, or electron beam. A radiation dose varies depending on the kind and content of the respective components in the composition, and the thickness of the coating film, but is from 100 to 2,000 mJ/cm² in the case of using an ultrahigh-pressure mercury lamp.

In the case of using a chemically amplified resist composition, generation and diffusion of an acid are promoted by heating using a known method after the exposure, and thus alkali solubility of a photoresist layer of the exposed is varied.

Then, a predetermined resist pattern is obtained by dissolving and removing the unnecessary portion using the developer composition of the present invention.

The developing time varies depending on the kind and content of the respective components in the composition, and the thickness of the dry coating film of the composition, but is usually from 1 to 30 minutes. The developing method may be any of a spin method, a dipping method, a paddle method and a spray developing method. After the development, the resist pattern is washed with running water for 30 to 90 seconds and then dried using an air gun or an oven.

Then, a connecting terminal such as metal post or bump can be formed by embedding a conductor such as metal into the non-resist portion (portion removed by an alkali developing solution) of the resist pattern thus obtained, through plating. The plating method is not specifically limited and various conventionally known methods can be employed. As the plating solution, a solder plating or copper plating solution is particularly preferably used.

The remained resist pattern is removed by a conventional method using a removing solution, finally.

The resist composition used in the method for forming a resist pattern of the present invention is not specifically limited, and a resist composition known as a resist composition used to form a thick-film resist pattern can be appropriately used. The resist composition may be a diazonaphthoquinone-novolak-based resist composition, or a chemically amplified resist composition. The resist composition may be a positive or negative resist composition. For example, resist compositions described in Japanese Unexamined Patent Application, First Publication No. 2002-258479, Japanese Unexamined Patent Application, First Publication No. 2003-043688, and Japanese Unexamined Patent Application, First Publication No. 2004-309775 can be used.

The developer composition of the present invention contains the above specific surfactant and defoaming agent and is therefore excellent in pattern forming ability and is less likely to cause frothing.

Specifically, since the developer composition contains an anionic surfactant represented by the general formula (I), the dissolution rate is high (developing sensitivity is high) and scum is less likely to be remained after the development. Also, thickness loss of a resist pattern does not occur and good residual film rate is attained. As a result, good effect can be obtained in view of the shape of a resist pattern and dimensional controllability.

When R² and/or R³ is —SO₃M (wherein M is a metal atom), it is commonly considered that the content of metal such as sodium, potassium or calcium is preferably as small as possible in a developer composition for resist in the semiconductor field. The reason is as follows. Namely, when ions are implanted through a resist pattern obtained by developing with a developer composition for resist in the developing step and rinsing with pure water, as a mask, if metal such as sodium or potassium is remained as impurities because of insufficient rinsing, electricity may be turned on and therefore it is disadvantageous. However, since an object of the present invention is to form a thick-film resist pattern, metal may be remained after the development.

Namely, in the application in which a thick-film resist pattern is formed and metal plating is conducted using the thick-film resist pattern as a mask to form a connecting terminal such as bump or metal post, the same developer composition for resist as that used in the semiconductor field has conventionally been used. However, in this application, since metal plating is conducted at the portion where a resist pattern is not formed, unlike the semiconductor field, which requires an operation of implanting ions, metal such as sodium, potassium or calcium may be remained.

Since the developer composition of the present invention contains the above specific defoaming agent, it is possible to obtain a property in which foam easily disappears even if frothing occurs, and a property in which frothing hardly occurs even if stirring is repeatedly conducted, without adversely affecting the effect of adding the surfactant. As described above, since the developer composition itself is less likely to cause frothing, a defoaming operation in a waste fluid tank is not required and thus the developer composition of the present invention is remarkably convenient.

### EXAMPLES

### Defoaming Reproducibility Test Example 1

With respect to the following defoaming agents 1 to 8, the defoaming reproducibility test described above was carried out. A developer body was prepared by adding an anionic surfactant represented by the following chemical formula to an aqueous 2.38 mass % tetramethylammonium hydroxide solution.

A developer body A is prepared by adding 20,000 ppm of a surfactant represented by the following chemical formula (I). A developer body B is prepared by adding 3,000 ppm of a surfactant represented by the following chemical formula (2). A developer body C is prepared by adding 1,000 ppm of a surfactant represented by the following chemical formula (3). A developer body D is prepared by adding 3,000 ppm of a surfactant represented by the following chemical formula (4). A developer body E is prepared by adding no anionic surfactant. In a blank test, pure water was used in place of the defoaming agent. The results are shown in Table 1 below.

In Table 1, the amount (unit: g) of a diluted defoaming agent solution added to 10 g of the developer body in the defoaming step and the amount of only the defoaming agent contained in the diluted defoaming agent solution, that is, “the amount of the defoaming agent in the defoaming step” are shown. Provided that a defoaming agent 5 was used in an amount of 0.1 g without being diluted.

Defoaming agent 1: KS-66 (silicone-based defoaming agent manufactured by Shin-Etsu Chemical Co., Ltd.)
Defoaming agent 2: TSA737 (silicone-based defoaming agent manufactured by GE Toshiba Silicones)
Defoaming agent 3: FS Antiform 544 (silicone-based defoaming agent manufactured by Dow Corning Co.)
Defoaming agent 4: FS Antiform 90 (silicone-based defoaming agent manufactured by Dow Corning Co.)
Defoaming agent 5: methanol (alcohol-based defoaming agent).
Defoaming agent 6: Pronal C-448 (nonionic surfactant-based defoaming agent manufactured by Toho Chemical Industry Co., Ltd.)
Defoaming agent 7: Pronal EX-300 (nonionic surfactant-based defoaming agent manufactured by Toho Chemical Industry Co., Ltd.)
Defoaming agent 8: Sodium dodecylsulfate (anionic surfactant-based defoaming agent)

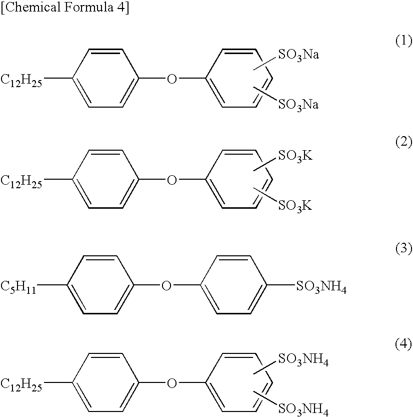

### Examples 1 to 18 and Comparative Examples 1 to 3

As the developer body, the above developer bodies A to D were used. As the defoaming agent, the defoaming agents 1 to used in the above Test Example 1 were used.

Developer compositions were prepared by adding 50 ppm of each defoaming agent to the developer bodies.

As the developer compositions of Comparative Examples 1 to 2, the developer bodies A and E, each containing no defoaming agent added therein, were used.

As the developer composition of Comparative Example 3, the developer body C containing, as the defoaming agent, the defoaming agent 8 (anionic surfactant-based defoaming agent) used in the above Test Example 1 added therein was used.

### (Evaluation)

On a 5 inch gold-sputtered wafer, a chemically amplified positive photoresist for thick film PMER P-CA1000PM (trade name, manufactured by Tokyo Ohka Kogyo Co., Ltd.) was applied at 1,800 rpm for 25 seconds using a spinner and then prebaked on a hot plate at 130° C. for 6 minutes to form a coating film having a thickness of about 20 μm, and thus a thick-film photoresist laminate was obtained.

In the case of forming a coating film having a thickness of about 25 μm, the photoresist was applied at 800 rpm for 25 seconds using a spinner and then prebaked on a hot plate at 130° C. for one minute, and thus a thick-film photoresist laminate was obtained.

The thick-film photoresist laminate thus obtained was exposed stepwise to ultraviolet ray within a range from 100 to 10,000 mJ/cm² through a pattern mask for the measurement of resolution using a stepper (NSR-2005i10D manufactured by Nikon Corporation). After exposure, the photoresist laminate was heated at 70° C. for 5 minutes and then developed with the above developer.

In a developing step, the photoresist laminate was developed by dipping in the resulting developer composition at 23° C. for 360 seconds, rinsed with pure water for 30 seconds and then dried.

Thereafter the dried product was subjected to washing with running water and nitrogen blowing, and a pattern-shape cured article was obtained. The resulting pattern-shape cured article was observed by a microscope and developability and resolution were evaluated according to the following criteria. The waste developer was accumulated in a waste fluid tank as a waste fluid. The evaluation results are shown in Table 1 below.

A target of the test chart rectile was a pattern which has a width of 1 to 40 μm and a rectangular cross section.

A pattern size of the bottom portion of the resist pattern thus obtained was measured by cross-section SEM (manufactured by Hitachi, Ltd. under the trade name of “S4000”).

(1) Dimensional Controllability: It is evaluated according to the following evaluation criteria.
A: The resist pattern thus formed has a size with a variation of tolerance within ±5% relative to a target of a mask pattern.
B: The resist pattern thus formed has a size with variation of tolerance within ±10% relative to a target of a mask pattern.
C: A variation of tolerance between the resist pattern thus formed and a mask pattern is more than ±10%.
(2) Scum Removing Properties: It is evaluated according to the following evaluation criteria.
A: Neither thin film residue nor scum residue is not recognized.
C: Thin film residue and scum residue are recognized.
(3) Frothing Suppressing Properties in Waste Fluid Tank: It is evaluated according to the following evaluation criteria.
A: When a waste fluid tank having a height of 1 m and an opening portion area of 1 m², which contains 500 liter or more of a waste fluid, the height of foam is 10 cm or less.
C: When a waste fluid tank having a height of 1 m and an opening portion area of 1 m², which contains 500 liter or more of a waste fluid, the height of foam is from 10 to 50 cm.
D: When a waste fluid tank having a height of 1 m and an opening portion area of 1 m², which contains 500 liter or more of a waste fluid, the height of foam is 50 cm or more.

TABLE 1

| | | Defoaming reproductivity test | | | | | | | | |
|---|---|---|---|---|---|---|---|---|---|---|
| | | Amount (g) | | | | | | | | |
| | | of diluted | | Height of | Height of | | | | | |
| | | defoaming agent | Amount (g) of | foam in | foam in | | | | | Frothing |
| | | solution per | defoaming agent | defoaming | refrothing | Develo- | Film | | Scum | suppression |
| | Defoaming | 10 g of | per 10 g of | step | step | per | thick- | Dimensional | removing | in waste |
| | agent | developer body | developer body | (H1) (mm) | (H1) (mm) | body | ness | stability | properties | fluid tank |
| Example 1 | Defoaming | 1 | 1 × 10⁻² | 0 | 2 | A | 20 | A | B | B |
| Example 2 | agent 1 | | | | | B | 20 | B | B | B |
| Example 3 | | | | | | C | 20 | B | B | B |
| Example 4 | | | | | | D | 20 | B | B | B |
| Example 5 | Defoaming | 1 | 1 × 10⁻² | 0 | 4 | A | 20 | A | B | B |
| Example 6 | agent 2 | | | | | B | 20 | B | B | B |
| Example 7 | | | | | | C | 20 | B | B | B |
| Example 8 | | | | | | D | 20 | B | B | B |
| Example 9 | Defoaming | 0.2 | 2 × 10⁻⁵ | 0 | 8 | A | 20 | A | B | B |
| Example-10 | agent 3 | | | | | A | 65 | A | B | B |
| Example 11 | Defoaming | 0.5 | 5 × 10⁻⁵ | 0 | 4 | B | 20 | B | B | B |
| Example 12 | agent 4 | | | | | B | 65 | B | B | B |
| Example 13 | Defoaming | 0.1 | 1 × 10⁻¹ | 0 | 20 | A | 65 | A | B | B |
| Example 14 | agent 5 | | | | | B | 65 | B | B | B |
| Example 15 | | | | | | C | 65 | B | B | B |
| Example 16 | | | | | | D | 65 | B | B | B |
| Example 17 | Defoaming | 1.3 | 1.3 × 10⁻² | 0 | 15 | C | 20 | B | B | B |
| | agent 6 | | | | | | | | | |
| Example 18 | Defoaming | 5.9 | 5.9 × 10⁻² | 0 | 13 | C | 65 | B | B | B |
| | agent 7 | | | | | | | | | |
| Comparative | Pure water | 1 | 0 (no addition) | 19 | — | A | 20 | A | B | D |
| Example 1 | | | | | | | | | | |
| comparative | | | | | | E | 20 | C | C | B |
| Example 2 | | | | | | | | | | |
| comparative | Defoaming | 2 | 1 × 10⁻¹ | 83 | — | C | 20 | B | B | D |
| Example 3 | agent 8 | | | | | | | | | |

As is apparent from the results shown in Table 1, in Examples 1 to 18, regarding dimensional controllability and scum removing properties, the same good results as in Comparative Example 1 or 3 are obtained and frothing suppressing properties in the waste fluid tank are noticeably excellent as compared with Comparative Examples 1 or 3. It was also found that, in Examples 1 to 18, dimensional controllability, and scum removing properties are noticeably excellent as compared with Comparative Example 2 in which the developer body E containing no anionic surfactant is used. As is apparent from the above results, the developer composition of the present invention is excellent in frothing suppressing properties in the waste fluid tank without adversely affecting dimensional controllability and scum removing properties.

1. A developer composition which is used to form a thick-film resist pattern on a substrate, comprising:
an organic quaternary ammonium base as a main component, an anionic surfactant represented by the following general formula (I), and a defoaming agent selected from the group consisting of a silicone-based defoaming agent, an alcohol-based defoaming agent and a nonionic surfactant-based defoaming agent: 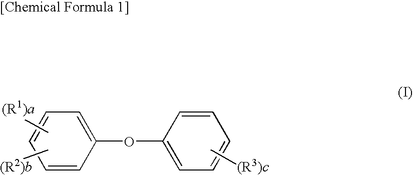
R¹ in the formula (I) represents an alkyl or alkoxy group having 5 to 18 carbon atoms and “a” represents 1 or 2; R² represents an ammonium sulfonate group, a substituted ammonium sulfonate group, or a group represented by the following general formula (II) and “b” represents an integer of 0 or 1 to 3; and R³ represents an ammonium sulfonate group, a substituted ammonium sulfonate group, or a group represented by the following general formula (II) and “c” represents an integer of 1 to 3, provided that when a plurality of R¹(s) are present, they may be the same or different from each other, when a plurality of R² (s) are present, they may be the same or different from each other, and when a plurality of R³ (s) are present, they may be the same or different from each other; and
[Chemical Formula 2]
—SO₃M (II)
wherein M in the formula (II) represents a metal atom.

2. The developer composition according to claim 1, wherein when the defoaming agent is applied to a defoaming reproducibility test including a frothing step of stirring 10 g of a developer body containing only the developer composition excluding the defoaming agent in a screw vial having a diameter of 40 mm and a capacity of 110 ml for 15 seconds to cause frothing, a defoaming step of adding the defoaming agent little by little after the frothing step until the height of the foam in the screw vial becomes 1 mm or less, and a refrothing step of measuring the height of the foam formed by stirring a liquid in the screw vial for 10 seconds after the defoaming step,
the amount of the defoaming agent added required until the foam disappears in the defoaming step is 2 g or less and the height of the foam measured in the refrothing step is 25 mm or less.

3. The developer composition according to claim 1, wherein the anionic surfactant is a compound represented by the following general formula (III): 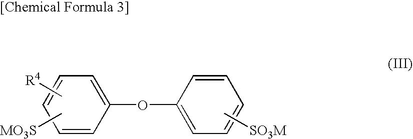
wherein R⁴ in the formula (III) is an alkyl or alkoxy group having 5 to 18 carbon atoms and M is a metal atom.

4. A method for forming a resist pattern, which comprises the steps of forming a thick-film resist layer having a thickness of 5 to 150 μm on a substrate, selectively exposing the thick-film resist layer, and developing the thick-film resist layer with the developer composition according to any one of claims 1 to 3 after the exposure to form a thick-film resist pattern.

5. A method for preparing a developer composition used to form a thick-film resist pattern on a substrate, which comprises:
adding a defoaming agent selected from the group consisting of a silicone-based defoaming agent, an alcohol-based defoaming agent and a nonionic surfactant-based defoaming agent to a developer body containing an organic quaternary ammonium base as a main component and an anionic surfactant represented by the following general formula (I): 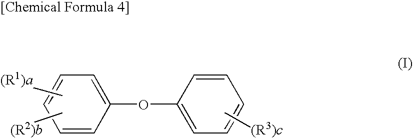
R¹ in the formula (I) represents an alkyl or alkoxy group having 5 to 18 carbon atoms and “a” represents 1 or 2; R² represents an ammonium sulfonate group, a substituted ammonium sulfonate group, or a group represented by the following general formula (II) and “b” represents an integer of 0 or 1 to 3; and R³ represents an ammonium sulfonate group, a substituted ammonium sulfonate group, or a group represented by the following general formula (II) and “c” represents an integer of 1 to 3, provided that when a plurality of R¹(s) are present, they may be the same or different from each other, when a plurality of R² (s) are present, they may be the same or different from each other, and when a plurality of R³(s) are present, they may be the same or different from each other; and
[Chemical Formula 5]
—SO₃M (II)
wherein M in the formula (II) represents a metal atom.

6. The method for preparing a developer composition according to claim 5, wherein when the defoaming agent is applied to a defoaming reproducibility test including a frothing step of stirring 10 g of a developer body containing only the developer composition excluding the defoaming agent in a screw vial having a diameter of 40 mm and a capacity of 110 ml for 15 seconds to cause frothing, a defoaming step of adding the defoaming agent little by little after the frothing step until the height of the foam in the screw vial becomes 1 mm or less, and a refrothing step of measuring the height of the foam formed by stirring a liquid in the screw vial for 10 seconds after the defoaming step,
the amount of the defoaming agent added required until the foam disappears in the defoaming step is 2 g or less and the height of the foam measured in the refrothing step is 25 mm or less.
